(19) United States
(12) Patent Application Publication
(10) Pub. No.: US 2026/0209640 A1
(43) Pub. Date: Jul. 23, 2026

(54) ETCHING COMPOSITION AND USE THEREOF

(71) Applicant: NINGBO ANJI MICROELECTRONICS TECHNOLOGY CO., Zhejiang (CN)

(72) Inventors: Zhang CHENG, Zhejiang (CN); Bing LIU, Zhejiang (CN); Hongxiu PENG, Zhejiang (CN); Bing WU, Zhejiang (CN)

(21) Appl. No.: 19/138,600

(22) PCT Filed: Dec. 7, 2023
(86) PCT No.: PCT/CN2023/136929

§ 371 Date: Jun. 12, 2025

(30) Foreign Application Priority Data
Dec. 13, 2022 (CN) 202211595622.4

(51) Int. Cl. C11D 3/30; C11D 1/44; C11D 1/52; C11D 1/62; C11D 1/66; C11D 1/72; C11D 3/00; C11D 3/20; C11D 3/28; C11D 3/33; C11D 3/34

(52) U.S. Cl. CPC C11D 3/30; C11D 1/44; C11D 1/528; C11D 1/62; C11D 1/66; C11D 1/72; C11D 3/0073; C11D 3/2086; C11D 3/28; C11D 3/33; C11D 3/3481; C11D 3/349

(57) ABSTRACT

The present invention provides an etching composition and its application. The etching composition comprises a hydroxylamine, a surfactant, a metal corrosion inhibitor, an amine pH modifier, an organic acid and water. The etching composition of the present invention can be used for the cleaning of cobalt layer processes above 7 nm, and has good cleaning ability for polymer residues, metal oxides, and fluorides after plasma ashing, as well as good compatibility with TiN and Low-K materials, and a large process operation window.

### TECHNICAL FIELD

The present invention relates to the field of chemical etching, particularly to an etching composition and its application.

### BACKGROUND

Moore's Law is approaching its limits as the feature size of IC chips continues to shrink and the scale of integration expands rapidly. In recent years, the mass production of EUV lithography makes the 7 nm process gradually mature, and the ensuing problem is that copper as the conductor material began to expose the conductivity rate is insufficient and other shortcomings, so that the process technology in the 10 nm, 7 nm node encountered a bottleneck. As a result, the trend is to use Co instead of Cu for some layers of the process above 7 nm, and the life of Moore's Law has thus been extended. Therefore, there is an urgent need for an etching composition that can be used to clean the cobalt process.

### DESCRIPTION

In order to provide an etching composition that can be used for cleaning of cobalt layer processes of 7 nm or more, and that has good cleaning ability for polymer residues, metal oxides, and fluorides after plasma ashing, the present invention provides an etching composition comprising a hydroxyl amine, a surfactant, a metal corrosion inhibitor, an amine pH adjuster, an organic acid, and water.

Preferably, the concentration of the hydroxylamine is 0.5% to 10%.

Preferably, the concentration of the surfactant is 0.001%~10%.

Preferably, the surfactant is selected from one or more of ethylene glycol monobutyl ether, ethylene glycol glycidyl ether, poly(ethylene glycol-propylene glycol) monobutyl ether, diethylene glycol dimethyl ether, propylene glycol phenyl ether, propylene glycol methyl ether, dodecyl amine polyoxymethylene ether, polyethylene glycol, polyethylene glycol-propylene glycol copolymer, Vinylpyrrolidone-vinylacetate copolymers, n-hexyl alcohol, 1,2-pentanediol, 1,2-propanediol, 1,3-propanediol, Benzyl alcohol, Dioxane, Ethanol, n-Propanol, Isopropanol, n-Butanol, SUPERWET-320, SUPERWET-340, SUPERWET-360, SUPERWET-420, SUPERWET-440, Coconutt Diethanol Amide, Dodecyl Trimethyl Ammonium Chloride, Myristyl Trimethyl Ammonium Chloride, Benzalkonium Chloride, Hexadecyl trimethylammonium bromide, tetraheptylammonium bromide.

Preferably, the concentration of the metal corrosion inhibitor is 0.1% to 5%.

Preferably, the metal corrosion inhibitor is selected from one or more of pyrazole, 1-methylpyrazole, 3,5-dimethylpyrazole, pyrazine, benzotriazole, methylbenzotriazole, 1H-benzotriazole methanol, 1,2,4-triazole-3-carboxylate methyl ester, 5-benzyl-1H-tetrazole, 1-phenyl-5-mercaptotetrazole, 5-benzothioyl-1H-tetrazole, 5-methyltetrazole, 2-mercaptotetrazole, methylmercaptoimidazole, mercaptoimidazole, 3-mercapto-4-methyl-4H-1,2,4-triazole.

Preferably, the concentration of the amine pH adjuster is 0.05% to 3%.

Preferably, the amine pH adjuster is selected from one or more of diethylene glycolamine, ethanolamine, ethylenediamine, diethanolamine, diethylenetriamine, triethylenetetramine, hydroxyethylethylenediamine, N-methylethanolamine, n-propanolamine, isopropanolamine, diisopropanolamine, triisopropanolamine, 1,8-diazabicyclo[5.4.0]undec-7-ene.

Preferably, the concentration of the organic acid is from 0.05% to 5%.

Preferably, the organic acid is a carboxylic acid having an N atom or an o atom at the α position.

Preferably, the organic acid is selected from one or more of a glycolic acid, lactic acid, mandelic acid, malic acid, citric acid, tartaric acid, gluconic acid, hydroxymalonic acid, pyridine-2-carboxylic acid, 2,3-pyridinedicarboxylic acid, 2,6-pyridinedicarboxylic acid, 1H-1,2,4-triazole-3-carboxylic acid, pyrazole-3-carboxylic acid, glycine, alanine, valine, leucine, isoleucine, methionine, proline, tryptophan, serine, tyrosine, cysteine, phenylalanine, asparagine, glutamine, threonine, aspartic acid, glutamic acid, lysine, arginine, histidine, pyrrolysine.

Another aspect of the present invention provides an application of the etching composition described in any one of the above for use in a process for cleaning a cobalt layer of 7 nm or more.

The etching composition of the present invention can be used for the cleaning of cobalt layer processes above 7 nm, and has good cleaning ability for polymer residues, metal oxides, and fluorides after plasma ashing, as well as good compatibility with TiN and Low-K materials, and a large process operation window.

### EMBODIMENTS

The advantages of the invention will be further explained in detail with reference to the following embodiments.

The etching compositions in Embodiments 1-10 were formulated using the respective components and contents listed in Table 1, wherein water was the remaining amount.

TABLE 1
Types and contents of each component of the etching
compositions in Embodiments 1-10

| | Hydroxyl- | Surfactants | | Metal Corrosion Inhibitors | | Amino PH Modifiers | | Organic Acids | | Deionized |
|---|---|---|---|---|---|---|---|---|---|---|
| Embod- | amines | | Specific | | Specific | | Specific | | Specific | Water |
| iment | Content | Content | compound | Content | compound | Content | compound | Content | compound | Content |
| 1 | 0.5 | 0.001 | SUPERWET- | 0.01 | Benzotriazole | 0.05 | diethylene | 0.05 | citrate | 99.3 |
| | | | 340 | | | | triamine | | | |
| 2 | 10 | 5.0 | Propylene | 3.0 | methylmercap- | 3.0 | 1,8- | 5.0 | glycolic | 74.0 |
| | | | glycol | | toimidazole | | Diazabicyclo | | acid | |
| | | | methyl | | | | [5.4.0] | | | |
| | | | ether | | | | undec-7-ene | | | |
| 3 | 4.5 | 0.25 | hexanol | 0.3 | 1H- | 1.5 | pyridoxine | 1.2 | tartaric | 92.5 |
| | | | | | Benzotriazo- | | | | acid | |
| | | | | | lemethanol | | | | | |
| 4 | 5 | 3 | Ethylene | 1.0 | 5- | 0.6 | diethylene | 0.5 | aspartic | 89.9 |
| | | | glycol | | Benzylthio- | | glycolamine | | acid | |
| | | | monobutyl | | 1H- | | | | | |
| | | | ether | | tetrazole | | | | | |
| 5 | 3.7 | 4.6 | polyethylene | 2.1 | mercapto- | 1.1 | isopropano- | 2.0 | Pyrazole- | 86.5 |
| | | | glycol | | imidazole | | lamine | | 3- | |
| | | | | | | | | | carboxylic | |
| | | | | | | | | | acid | |
| 6 | 4.5 | 0.3 | Dodecylamine | 0.5 | Methylbenzo- | 1.3 | hydroxy- | 1.9 | glycine | 91.8 |
| | | | polyoxyethylene | | triazole | | ethylethylene | | | |
| | | | ether | | | | diamine | | | |
| 7 | 4.8 | 0.005 | Coconutt | 0.07 | Methyl | 0.4 | Triiso- | 0.7 | gluconic | 94.0 |
| | | | Diethanol | | 1,2,4- | | propanolamine | | acid | |
| | | | Amide | | triazole-3- | | | | | |
| | | | | | carboxylate | | | | | |
| 8 | 7.2 | 0.003 | Dodecyltri- | 2.6 | pyrazole | 1.0 | Diisopro- | 0.8 | 2,3- | 88.4 |
| | | | methylammonium | | | | panolamine | | Pyridine- | |
| | | | chloride | | | | | | dicarboxylic | |
| | | | | | | | | | acid | |
| 9 | 3.6 | 2.0 | Ethylene | 0.1 | 2- | 0.6 | N- | 0.5 | 2,6- | 93.2 |
| | | | glycol | | Mercapto- | | Methyl- | | Pyridine- | |
| | | | glycidyl | | thiadiazole | | ethanolamine | | dicarboxylic | |
| | | | ether | | | | | | acid | |
| 10 | 5.0 | 0.002 | SURFYNOL420 | 0.2 | 3-mercapto- | 0.6 | triethyl- | 1.0 | mandelic | 93.2 |
| | | | | | 4-methyl- | | enetetramine | | acid | |
| | | | | | 4H-1,2,4- | | | | | |
| | | | | | triazole | | | | | |

In order to detect the compatibility of the etching compositions on a variety of materials, test the etching rate of metal Co, TiN, non-metallic Oxide, SiN, in which the metal etching rate test method is as follows, the selection of Co, TiN blanket wafers (blanket wafer), the blanket wafer sliced to the size of 5*5 cm, placed in a single rotary cleaning machine under the treatment, the processing time range of 3-20 min, preferably 10 min, the speed setting range of 200-900 rpm, preferably 600 rpm. 20 min, preferably 10 min, the speed setting range of 200-900 rpm, preferably 600 rpm, the test temperature of 25~70° C., preferably 50° C. after processing, take out the rinsing and blow-dry with high-purity nitrogen.

The corrosion rate test methods are as follows:
1) Test the resistance (R1) of a 5*5 cm metal blank wafer to be tested using a metal film thickness gauge;
2) The 5*5 cm metal blank wafer to be tested in the monolithic rotary cleaning machine processing;
3) Remove the 5*5 cm metal blank wafer, clean it with deionized water, blow dry it with high-purity nitrogen, and then test the resistance (R2) of the metal blank wafer using the metal film thickness gauge;
4) The etching rate can be calculated by inputting the change of the above resistance value and the processing time into a suitable program.

Its calculation formula is as follows:

$$ER = K ( R 2 - R 1 ) / T$$

R1 and R2 are the resistance values of the metal blank wafers; T is the processing time of the microcontroller; K value is the coefficient, and the K values of different metal materials are different. The unit of metal corrosion rate is A/min.

Non-metallic corrosion materials (SiN, Oxide) etching rate test method is as follows:
1) Test the first thickness D1 of the non-metallic material layer (AlN) of the 5*5 cm non-metallic blank wafer to be tested using ellipsometry;
2) Place the 5*5 cm non-metallic blank wafer to be tested in a monolithic rotary cleaner for 10 min, with the rotational speed set at 600 rpm;
3) Removing this blank wafer, cleaning it with deionized water, blowing it dry with high-purity nitrogen, and then testing the second thickness D2 using ellipsometry;
(4) The corrosion rate can be calculated by inputting the change of the above thickness value and the processing time into a suitable program. Its calculation formula is as follows:

$$ER = ( D 1 - D 2 ) / T$$

Where D1 and D2 are the first thickness and the second thickness of the non-metallic blank wafer, respectively, and T is the time of treatment.

The specific test results are shown in Table 2.

TABLE 2
Test Etch results of Embodiments 1-10

| | | | | Co | TiN | Oxide | SiN |
|---|---|---|---|---|---|---|---|
| | | | | etching | etching | etching | etching |
| | Operating | Operating | Speed | rate | rate | rate | rate |
| Embodiment | temperature (° C.) | time (min) | (rpm) | (Å/min) | (Å/min) | (Å/min) | (Å/min) |
| 1 | 70 | 20 | 900 | 2.4 | 1.1 | 0.3 | 0.9 |
| 2 | 25 | 3 | 200 | 1.1 | 0.3 | 0.2 | 0.4 |
| 3 | 45 | 10 | 600 | 0.3 | 0.9 | 0.1 | 0.3 |
| 4 | 50 | 10 | 600 | 0.7 | 1.9 | 1.3 | 0.8 |
| 5 | 40 | 15 | 400 | 1.0 | 1.0 | 0.8 | 1.2 |
| 6 | 60 | 15 | 500 | 1.3 | 1.2 | 0.7 | 0.6 |
| 7 | 55 | 12 | 400 | 0.9 | 1.6 | 1.1 | 0.7 |
| 8 | 65 | 10 | 800 | 2.3 | 2.7 | 0.9 | 0.7 |
| 9 | 30 | 5 | 600 | 0.2 | 0.7 | 0.1 | 0.3 |
| 10 | 50 | 10 | 600 | 1.2 | 1.9 | 2.0 | 1.1 |

Based on the above test results, it can be seen that the etching compositions of Embodiments 1-10 are more compatible with Co, TiN, SiN, and oxides at different temperatures, rotational speeds, and operating times, and the etching rate is lower.

The etching compositions of Embodiments 11-14 and the Comparative Embodiments 1-3 were prepared in accordance with the components and corresponding contents listed in Table 3.

TABLE 3
Components and their contents of the etching compositions
of Embodiments 11-14 of the present invention as well as of the
Comparative Embodiments 1-3

| | | | | Metal Corrosion | | Amino PH | | | | |
|---|---|---|---|---|---|---|---|---|---|---|
| | | Surfactants | | Inhibitors | | Modifiers | | Organic Acids | | Deionized |
| | Hydroxylamines | | Specific | | Specific | | Specific | | Specific | Water |
| Embodiment | Content | Content | compound | Content | compound | Content | compound | Content | compound | Content |
| 11 | 4.5 | 3 | Ethylene | 0.4 | 5- | 0.9 | diethylene | 0.5 | Pyrazole- | 90.7 |
| | | | glycol | | Benzylmercapto- | | glycolamine | | 3- | |
| | | | monobutyl | | 1H- | | | | carboxylic | |
| | | | ether | | tetrazole | | | | acid | |
| 12 | 4.5 | 3 | Ethylene | 0.2 | 5- | 0.9 | diethylene | 0.5 | Pyrazole- | 90.9 |
| | | | glycol | | Benzylmercapto- | | glycolamine | | 3- | |
| | | | monobutyl | | 1H- | | | | carboxylic | |
| | | | ether | | tetrazole | | | | acid | |
| 13 | 4.5 | 3 | Ethylene | 0.4 | 5- | 0.4 | diethylene | 0.5 | Pyrazole- | 91.2 |
| | | | glycol | | Benzylmercapto- | | glycolamine | | 3- | |
| | | | monobutyl | | 1H- | | | | carboxylic | |
| | | | ether | | tetrazole | | | | acid | |
| 14 | 4.5 | 3 | Ethylene | 0.4 | 5- | 0.9 | diethylene | 0.2 | Pyrazole- | 91.0 |
| | | | glycol | | Benzylmercapto- | | glycolamine | | 3- | |
| | | | monobutyl | | 1H- | | | | carboxylic | |
| | | | ether | | tetrazole | | | | acid | |
| Comparative | 4.5 | 3 | Ethylene | | | 0.9 | diethylene | 0.5 | Pyrazole- | 91.1 |
| Embodiment | | | glycol | | | | glycolamine | | 3- | |
| 1 | | | monobutyl | | | | | | carboxylic | |
| | | | ether | | | | | | acid | |
| Comparative | 4.5 | 3 | Ethylene | 0.4 | 5- | | | 0.5 | Pyrazole- | 91.6 |
| Embodiment | | | glycol | | Benzylmercapto- | | | | 3- | |
| 2 | | | monobutyl | | 1H- | | | | carboxylic | |
| | | | ether | | tetrazole | | | | acid | |
| Comparative | 4.5 | 3 | Ethylene | 0.4 | 5- | 0.9 | diethylene | | | 91.2 |
| Embodiment | | | glycol | | Benzylmercapto- | | glycolamine | | | |
| 3 | | | monobutyl | | 1H- | | | | | |
| | | | ether | | tetrazole | | | | | |

In order to further investigate the compatibility of such compositions on the material, the present invention adopts the following technical means: test the etching rate of metal Co, TiN, non-metal Oxide, SiN, in which the metal etching rate test method is as follows, choose Co, TiN blank wafers (blanket wafer), blank wafers will be sliced to the size of 5*5 cm, placed in a single rotary cleaning machine under the Processing, processing time range of 3-20 min, this choice of 10 min, speed setting range of 200-900 rpm, this choice of 600 rpm, the test temperature of 25~70° C., this choice of 50° C., after processing, take out the rinsing with high-purity nitrogen gas blow dry.

Corrosion rate test methods are as follows:
1) Test the resistance (R1) of a 5*5 cm metal blank wafer to be tested using a metal film thickness gauge;
2) The 5*5 cm metal blank wafer to be tested in the monolithic rotary cleaning machine processing;
3) Remove the 5*5 cm metal blank wafer, clean it with deionized water, blow dry it with high-purity nitrogen, and then test the resistance (R2) of the metal blank wafer using the metal film thickness gauge;
4) The etching rate can be calculated by inputting the change of the above resistance value and the processing time into a suitable program. Its calculation formula is as follows:

$$ER = K ( R 2 - R 1 ) / T$$

R1 and R2 are the resistance values of the metal blank wafers; T is the processing time of the microcontroller; K value is the coefficient, and the K values of different metal materials are different. The unit of metal corrosion rate is A/min.

Non-metallic corrosion materials (SiN, Oxide) etching rate test method is as follows:
1) Test the first thickness D1 of the non-metallic material layer (AlN) of the 5*5 cm non-metallic blank wafer to be tested using ellipsometry;
2) Place the 5*5 cm non-metallic blank wafer to be tested in a monolithic rotary cleaner for 10 min, with the rotational speed set at 600 rpm;
3) Removing this blank wafer, cleaning it with deionized water, blowing it dry with high-purity nitrogen, and then testing the second thickness D2 using ellipsometry;
4) The corrosion rate can be calculated by inputting the change of the above thickness value and the processing time into a suitable program. Its calculation formula is as follows:

$$ER = ( D 1 - D 2 ) / T$$

D1 and D2 are the first thickness and the second thickness of the non-metallic blank wafer, respectively; T is the processing time. The specific test results are shown in Table 4.

TABLE 4
Etch rates of blank wafers for Embodiments 11-14 and Comparative
Embodiments 1-3 of the present invention

| | | | | Co | TiN | Oxide | SiN |
|---|---|---|---|---|---|---|---|
| | Operating | | | etching | etching | etching | etching |
| | temperature | Operating | Speed | rate | rate | rate | rate |
| Embodiment | (° C.) | time (min) | (rpm) | (Å/min) | (Å/min) | (Å/min) | (Å/min) |
| 11 | 50 | 10 | 600 | 0.5 | 2.0 | 0.3 | 0.6 |
| 12 | 50 | 10 | 600 | 2.2 | 5.7 | 0.2 | 0.7 |
| 13 | 50 | 10 | 600 | 1.3 | 4.2 | 0.6 | 1.1 |
| 14 | 50 | 10 | 600 | 0.1 | 0.3 | 0.0 | 0.1 |
| Comparative | 50 | 10 | 600 | 38.5 | 10.2 | 0.4 | 0.5 |
| Embodiment 1 | | | | | | | |
| Comparative | 50 | 10 | 600 | 6.7 | 7.6 | 0.7 | 0.6 |
| Embodiment 2 | | | | | | | |
| Comparative | 50 | 10 | 600 | 0.1 | 0.0 | 0.1 | 0.1 |
| Embodiment 3 | | | | | | | |

As can be seen from Embodiment 11, Embodiment Embodiment 12 and Comparative Embodiment 1 in Table 4, the metal corrosion inhibitor 5-benzylmercapto-1H-tetrazole can greatly reduce the Co etching rate, and at the same time protect TiN from corrosion to a certain extent. As can be seen from Embodiment 11, Embodiment 13 and Comparative Embodiment 2, the amine PH modifier can achieve the effect of reducing the Co and TiN etching rate by adjusting the PH. As can be seen from Embodiment 11, Embodiment 14 and Comparative Embodiment 3, the etching rate of metallic materials is reduced when the content of organic acids is reduced, and the etching rate of non-metallic materials is also reduced.

The etching compositions in Embodiments 15-16 and Comparative Embodiments 4-5 were formulated in accordance with the components and corresponding contents listed in Table 5.

TABLE 5
Components and their contents of the etching compositions of
Embodiments 15-16 of the present invention as well as of the
Comparative Embodiments 4-5

| | | | | Metal Corrosion | | | | | | |
|---|---|---|---|---|---|---|---|---|---|---|
| | | Surfactants | | Inhibitors | | Amino PH Modifiers | | Organic Acids | | Deionized |
| | Hydroxylamines | | Specific | | Specific | | Specific | | Specific | Water |
| Embodiment | Content | Content | compound | Content | compound | Content | compound | Content | compound | Content |
| 15 | 5.0 | 3 | Ethylene | 0.4 | Methylbenzo | 0.9 | diethylene | 0.5 | lactic | 90.2 |
| | | | glycol | | triazole | | glycolamine | | acid | |
| | | | monobutyl | | | | | | | |
| | | | ether | | | | | | | |
| 16 | 5.0 | 3 | Ethylene | 0.4 | Methylbenzo | 0.9 | diethylene | 0.5 | Pyridine- | 90.2 |
| | | | glycol | | triazole | | glycolamine | | 2- | |
| | | | monobutyl | | | | | | carboxylic | |
| | | | ether | | | | | | acid | |
| Comparative | 5.0 | 3 | Ethylene | 0.4 | Methylbenzo | 0.9 | diethylene | 0.5 | diethylenetri- | 90.2 |
| Embodiment | | | glycol | | triazole | | glycolamine | | amine | |
| 4 | | | monobutyl | | | | | | pentaacetic | |
| | | | ether | | | | | | acid | |
| Comparative | 5.0 | 3 | Ethylene | 0.4 | Methylbenzo | 0.9 | diethylene | 0.5 | malonic | 90.2 |
| Embodiment | | | glycol | | triazole | | glycolamine | | acid | |
| 5 | | | monobutyl | | | | | | | |
| | | | ether | | | | | | | |

In order to examine the organic residue status of the composition after treatment of the wafer surface, the present invention adopts the following technical means: select Co blank wafers (blanket wafer), blank wafers sliced to 5*5 cm size, placed in a monolithic rotary cleaning machine under the treatment, the processing time is selected as 3 min, the rotational speed setting is selected as 600 rpm, and the temperature of the test is selected as 40° C. After processing, it was taken out and placed under the monolithic rotary cleaner for rinsing, the processing time was selected to be 30 s, the rotational speed setting was selected to be 600 rpm, and the rinsing temperature was selected to be 25° C. Finally, it was blown dry with high-purity nitrogen, and the elemental abundance of C, N, O, and Co on the surface of the wafer was tested by XPS. The specific test results are shown in Table 6.

TABLE 6
XPS results of treated Co wafer surface

| Embodiment | C 1s | N 1s | O 1s | Co 2p |
|---|---|---|---|---|
| Embodiment 15 | 45.20 | 4.55 | 29.00 | 21.25 |
| Embodiment 16 | 42.19 | 3.17 | 31.36 | 23.28 |
| Comparative | 46.80 | 5.51 | 29.42 | 18.27 |
| Embodiment 4 | | | | |
| Comparative | 45.89 | 7.31 | 27.74 | 19.06 |
| Embodiment 5 | | | | |

As can be seen in Table 6, the Co surface after treatment of the described composition embodiments has a higher Co abundance and lower N and C abundance, indicating that the amount of residual organic matter is lower in this system compared to the proportional system, which facilitates subsequent operations in the Co layer, for example, facilitating the filling of the relevant structure with W or other metals.

TABLE 7
Test results of Co ion content
(ppb) for Embodiments 15 and 16

| | CoO | CoF2 |
|---|---|---|
| | processing | processing |
| [symbol] | results | results |
| Embodiment 15 | 30.2 | 883.6 |
| Embodiment 16 | 41.9 | 1307.6 |
| Blank | 1.02 | 5.12 |
| Experiment | | |

Table 7 shows the solubility of CoF2 and CoO in some embodiments, and the blank is deionized water. The testing method used in the present invention is: take equal amount of CoF2/CoO dissolved in 1 L of the composition solution or water respectively, and test the Co ion concentration by ICP-MS after stabilization. It can be seen that the dissolving ability of the composition of the present invention for CoF2/CoO is much larger than that of deionized water.

Based on the above embodiments and the test results of the proportions, it can be seen that the etching compositions of the present invention have better cleaning ability for polymer residues, metal oxides and fluoride after plasma ashing, and at the same time, they have very good compatibility for TiN and Low-K materials, have a large window for process operation, and have a broad application prospect.

Although the above specific embodiments of the present invention have been described in detail, they are only Embodiments, and the present disclosure is limited to the embodiments described above. For those skilled in the art, any equivalent modification and substitution to the present invention is also covered in the present invention. Therefore, all these equivalent changes and modifications made without departing from the spirit and scope of the invention should be covered within the scope of the present invention.

1. An etching composition comprising a hydroxylamine, a surfactant, a metal corrosion inhibitor, an amine pH modifier, an organic acid, and water.

2. The etching composition according to claim 1, wherein the concentration of the hydroxylamine is 0.5% to 10%.

3. The etching composition according to claim 1, wherein the concentration of the surfactant is 0.001%-10%.

4. The etching composition according to claim 1, wherein, the surfactant is selected from one or more of ethylene glycol monobutyl ether, ethylene glycol glycidyl ether, poly(ethylene glycol-propylene glycol) monobutyl ether, diethylene glycol dimethyl ether, propylene glycol phenyl ether, propylene glycol methyl ether, dodecyl amine polyoxymethylene ether, polyethylene glycol, polyethylene glycol-propylene glycol copolymer, Vinylpyrrolidone-vinylacetate copolymers, n-hexyl alcohol, 1,2-pentanediol, 1,2-propanediol, 1,3-propanediol, Benzyl alcohol, Dioxane, Ethanol, n-Propanol, Isopropanol, n-Butanol, SUPERWET-320, SUPERWET-340, SUPERWET-360, SUPERWET-420, SUPERWET-440, Coconutt Diethanol Amide, Dodecyl Trimethyl Ammonium Chloride, Myristyl Trimethyl Ammonium Chloride, Benzalkonium Chloride, Hexadecyl trimethylammonium bromide, tetraheptylammonium bromide.

5. The etching composition according to claim 1, wherein the concentration of the metal corrosion inhibitor is 0.1% to 5%.

6. The etching composition according to claim 1, wherein the metal corrosion inhibitor is selected from one or more of pyrazole, 1-methylpyrazole, 3,5-dimethylpyrazole, pyrazine, benzotriazole, methylbenzotriazole, 1H-benzotriazole methanol, 1,2,4-triazole-3-carboxylate methyl ester, 5-benzyl-1H-tetrazole, 1-phenyl-5-mercaptotetrazole, 5-benzothioyl-1H-tetrazole, 5-methyltetrazole, 2-mercaptotetrazole, methylmercaptoimidazole, mercaptoimidazole, 3-mercapto-4-methyl-4H-1,2,4-triazole.

7. The etching composition according to claim 1, wherein the concentration of the amine pH adjuster is 0.05% to 3%.

8. The etching composition according to claim 1, wherein the amine pH adjuster is selected from one or more of diethylene glycolamine, ethanolamine, ethylenediamine, diethanolamine, diethylenetriamine, triethylenetetramine, hydroxyethylethylenediamine, N-methylethanolamine, n-propanolamine, isopropanolamine, diisopropanolamine, triisopropanolamine, 1,8-diazabicyclo[5.4.0]undec-7-ene.

9. The etching composition according to claim 1, wherein the concentration of the organic acid is from 0.05% to 5%.

10. The etching composition according to claim 1, wherein the organic acid is a carboxylic acid having an N atom or an O atom at the α position.

11. The etching composition according to claim 10, wherein the organic acid is selected from one or more of a glycolic acid, lactic acid, mandelic acid, malic acid, citric acid, tartaric acid, gluconic acid, hydroxymalonic acid, pyridine-2-carboxylic acid, 2,3-pyridinedicarboxylic acid, 2,6-pyridinedicarboxylic acid, 1H-1,2,4-triazole-3-carboxylic acid, pyrazole-3-carboxylic acid, glycine, alanine, valine, leucine, isoleucine, methionine, proline, tryptophan, serine, tyrosine, cysteine, phenylalanine, asparagine, glutamine, threonine, aspartic acid, glutamic acid, lysine, arginine, histidine, pyrrolysine.

12. An application of the etching composition as claimed in claim 1 for use in a process for cleaning a cobalt layer of 7 nm or more.
